(19) United States
(12) Patent Application Publication
(10) Pub. No.: US 2003/0234438 A1
(43) Pub. Date: Dec. 25, 2003

(54) Integrated circuit structure for mixed-signal RF applications and circuits

(75) Inventors: Wen Ling M Huang, Scottsdale, AZ (US); James Kirchgessner, Tempe, AZ (US); David Monk, Gilbert, AZ (US)

Correspondence Address: Tyson Winarski, Suite 1600, 201 East Washington Street, Phoenix, AZ, 85004, US

(73) Assignee: Motorola, Inc.

(21) Appl. No.: 10/178,672

(22) Filed: Jun. 24, 2002

(51) Int. Cl. H01L 29/00

(52) U.S. Cl. 257/547

(57) ABSTRACT

An integrated circuit that supports digital circuits, analog circuits, and RF circuits on a single IC. Digital CMOS circuitry lies on a low resistivity layer that provides good latch-up qualities and allows for dense PAD I/O. Analog CMOS circuitry rests on an isolated well region on a highly resistive layer in order to minimize signal crosstalk through the substrate. Analog BJT devices also sit on a highly resistive region within its own well structure in order to minimize parasitic capacitances and provide for high frequency device switching. RF passive elements, such as inductors and capacitors, rest on a highly resistive region in order to minimize signal losses that especially occur at high frequencies. RF active components rest on a highly resistive region to maximize device performance.

### TECHNICAL FIELD OF THE INVENTION

The present invention relates to the field of integrated circuits and, more particularly, to integrated circuits that support digital circuits, analog circuits, and Radio-Frequency (RF) circuits on a single microchip.

### BACKGROUND OF THE INVENTION

It is highly desirable to have a single Integrated Circuit (IC) that can support digital, analog, and RF circuit elements. By integrating each of these circuit types into a single IC, it is possible to greatly improve the qualities and cost of portable RF devices for wireless and optical communication applications. The integration, however, of these various circuit types presents several unique problems.

For example, placing each of these various device types on a single IC often allows inter-circuit interaction through the IC substrate. Such interaction can greatly degrade and inhibit the expected operation of the IC when digital, analog, and RF circuit elements are placed on the same substrate.

The differential noise sensitivity of dissimilar circuit types spawns another problem. Analog circuitry is sensitive to electrical noise produced by other circuits and devices. To function effectively, analog circuitry is isolated from electrical noise. On the other hand, digital circuits are far less sensitive to electrical noise due to their digital nature. The low voltage swing of an analog device produces little noise. Further, the current bases for analog circuitry keeps noise levels low. Consequently, analog circuits produce low noise levels. However, digital circuits produce a significant amount of electrical noise due to the large rail to rail voltage swings of the devices. Integrating analog and digital circuit elements onto a single IC typically exposes the analog circuit elements to the high noise component produced by the digital circuit elements. To integrate analog and digital circuit components on a single IC, analog circuit components must be isolated and insulated from the electrical noise produced by digital circuit components.

Another problem spawned by dissimilar circuitry is latch-up. In latch-up, digital CMOS circuits become “stuck” in a specific logic state. Simply stated, latch-up is caused by an internal feedback mechanism associated with parasitic PNPN-like action. When integrating digital, analog, and RF circuit elements together on a single IC, latch-up avoidance is an important goal.

Signal crosstalk also plagues dissimilar device circuitry. Crosstalk is interference caused by two or more signals becoming partially superimposed on each other due to electromagnetic (inductive) or electrostatic (capacitive) coupling between devices or conductors carrying the signals. In CMOS circuits, this interference between devices can produce false switching in other parts of the system. Consequently, it is highly desirable to develop an IC that can support analog, digital, and RF components while reducing crosstalk to ensure high performance and reliability.

Signal losses in the RF circuit, especially in the high frequency region are also often exhibited in mixed device ICs. One measure of an RF circuit is the quality factor. Efficient RF circuits with minimal signal losses have a high quality factor. RF components with a low quality factor typically require additional circuitry stages that are necessary to compensate for the consequent signal and energy losses. These additional stages consume valuable chip space and reduce the efficiency of the overall device. One of the causes of this signal and energy degradation, measured by the quality factor, is undesirable capacitive coupling between RF devices and the substrate. This coupling reduces the quality factor. In addition, electrical eddy currents within the substrate also reduce the quality factor of RF devices. It is, therefore, highly desirable to develop an IC structure that has RF devices with a high quality factor to improve the overall IC operation for high frequency applications and reduce the amount of circuitry needed to support the applications.

One technology known to the art that addresses some of these problems is disclosed in U.S. Pat. No. 6,348,719 (the “'719”) assigned to Texas Instruments. The '719 patent purports to teach an integrated circuit based on only CMOS logic for use at high frequencies that integrates active CMOS components with passive components. Purportedly all active CMOS components are formed on a high specific resistivity layer on the order of a thousand ohm-cm. In the semiconductor substrate, and under the active CMOS components, a buried layer is formed that has a low specific resistivity in the order of magnitude of one ohm-cm. The passive components are formed in or on a layer of insulating material which is arranged on the semiconductor substrate.

To maximize the efficiency and operation of ICs for high frequency applications, it is not desirable to place all active CMOS components on a high resistivity layer. It is also desirable to develop a single integrated circuit that can support digital, analog, and RF circuit elements using BiCMOS technology.

### SUMMARY OF THE INVENTION

The present invention provides a semiconductor structure that facilitates the integration of digital, analog, and RF circuits into a single IC. More specifically, the present invention provides a structure that reduces the interaction of digital circuits, analog circuits, and RF circuits on a single IC through the substrate. The present invention reduces cross-circuit interaction through the substrate by strategically positioning the various components over either a patterned low resistivity layer or the remaining high resistivity substrate region. For the p-type substrate, the low resistivity layer is a patterned p+ buried layer. The high resistivity region is the region outside of the p+ buried layer. Similarly, for an n-type substrate, the low resistivity layer is a patterned n+ buried layer and the high resistivity region is the area outside of the n+ buried layer. The formation of the patterned buried layer can be achieved by high energy ion implantation or by formation of a highly doped region followed by an epitaxial silicon deposition. The epitaxial layer is high resistivity and can be p-type, n-type or intrinsic.

In the present invention, digital CMOS circuitry is positioned over a low resistivity layer that provides good latch-up immunity and allows for dense PAD I/O. Analog CMOS circuitry rests on an isolated well region in the high resistivity substrate region to minimize signal crosstalk. Analog BJT devices rest in the highly resistive substrate region within their own well structures to minimize parasitic capacitances and encourage for high frequency device switching. RF passive elements, such as inductors and capacitors, rest in or over the highly resistive substrate region to minimize signal losses that may occur at high frequencies. By enabling integration of these various device and circuit types, the present invention improves the qualities and cost of portable RF devices for wireless and optical communication applications.

The strategic placement of the circuit components in or over either the low or high resistivity regions insulates and isolates the various components from noise produced from other devices or circuits located on the IC. Low resistivity regions reduce noise by providing a low resistance path that signals can travel through away from regions where noise sensitive circuits reside. High resistivity regions within the substrate reduce signal crosstalk by attenuating the electrical signals.

### BRIEF DESCRIPTION OP THE DRAWINGS

FIG. 1 depicts a cross section that illustrates a preferred embodiment of the present invention.

FIG. 2 depicts a semiconductor having a preferred structure of patterning a low resistivity buried layer in a preferred embodiment of the present invention.

FIG. 3 depicts a semiconductor having an alternative structure of patterning a low resistivity buried layer in a preferred embodiment of the present invention.

FIG. 4 depicts a cross section of an isolated analog circuit element in a preferred embodiment of the present invention.

FIG. 5 depicts a view of an isolated digital circuit block fabricated in accordance with a preferred embodiment of the present invention.

FIG. 6 depicts a heterojunction bipolar transistor formed in a integrated circuit made in accordance with a preferred embodiment of the present invention.

FIG. 7 depicts a varactor formed in a integrated circuit made in accordance with a preferred embodiment of the present invention.

### DETAILED DESCRIPTION OF A PREFERRED EMBODIMENT

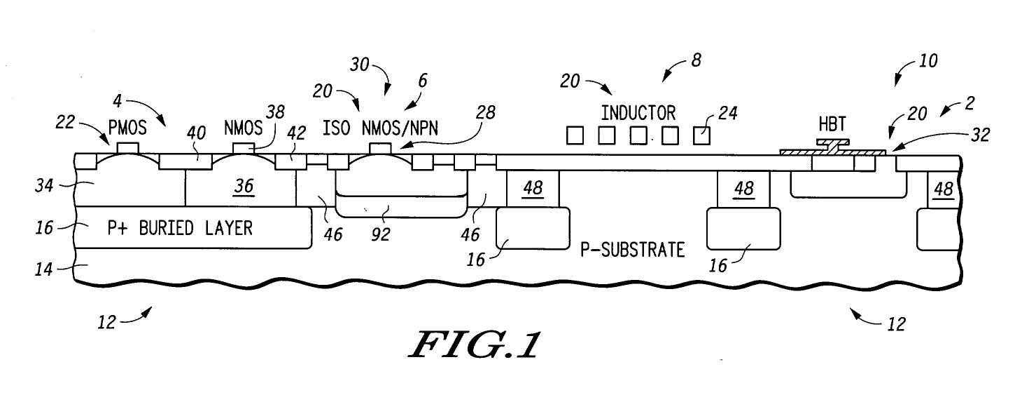

Referring to the Figures by characters of reference, FIG. 1 depicts a cross section of an Integrated Circuit (IC) 2 fabricated in accordance with a preferred embodiment of the present invention in a p-type substrate. For an n-type substrate, an n-type buried layer would replace the p-type buried layer. As shown in FIG. 1, IC 2 supports digital components 4, analog components 6, passive RF components 8, and active RF components 10. IC 2 is able to support digital components 4, analog components 6, passive RF components 8, and active RF components 10 through having an isolating structure 12 that reduces electrical interaction between these various components through high resistivity substrate 14. Electrically, substrate 14 is essentially a resistor that connects all devices on IC 2. Through insulating and isolating these various components, it is possible to integrate digital components 4, analog components 6, passive RF components 8, and active RF components 10 on a single IC 2. Strategically placing these components in or over either a low resistivity buried layer 16, or a high resistivity substrate 14, makes it possible to integrate these various components on a single IC 2 while maximizing their individual performance. Through the use of a low resistivity layer 16, a high resistivity substrate 14, and well structures 20, it is possible to insulate and isolate the various components and integrate them all onto a single IC 2.

A CMOS digital circuit element 22 rests on a low resistivity buried layer 16. Passive RF circuit elements 8 such as, for example, inductor 24 rest on a highly resistive substrate 14. Analog circuit elements 6 such as NMOS 26 or NPN BJT 28 rest within an isolated well 30 in a highly resistive substrate 14. Active RF elements 10 such as Heterojunction Bipolar Transistor (HBT) 32 rest in a high resistivity region 14 to maximize the performance of HBT 32.

CMOS 22 is comprised of a PMOS 34 and an NMOS device 36. Each MOS device 22 has a gate 38, a source 40, and a drain 42. Placing CMOS digital circuit element 22 on low resistivity buried layer 16 has several advantages. First, buried layer 16 reduces the occurrence of latch-up between CMOS devices 22. Latch-up is a condition under which significant current flows through substrate 14 between NMOS 36 and PMOS 34 parts of CMOS 22 and degrades its performance. Latch-up causes the CMOS circuitry 22 to fix in a specific logic state. Simply stated, latch-up is caused by an internal feedback mechanism associated with parasitic PNPN-like action. However, through providing a low resistance current path under CMOS 22, buried layer 16 reduces the occurrence of latch-up.

Second, the low resistivity buried layer 16 acts like a noise sink. CMOS digital circuitry 22 produces significant levels of noise due to the large rail to rail voltage swing of the devices 22. This electrical noise is diverted from the device through the low resistivity buried layer 16. Third, buried layer 16 is strategically positioned under just digital CMOS components 22. In this manner, the noise in buried layer 16 is generally restricted to digital CMOS components 22.

Analog CMOS components 44 rest on a highly resistive substrate 14. Highly resistive substrate 14 attenuates the noise from the buried layer 16 thereby isolating and insulating analog CMOS components 44 from digital CMOS components 22. While the remaining digital CMOS components 22 are exposed to the noise from buried layer 16, the digital nature of CMOS components 22 makes them relatively insensitive to noise.

Buried layer 16, while depicted in conjunction with digital CMOS 22, is also used along with various well structures to isolate other electrically noisy devices within IC 2. An example of an electrically noisy device is a charge pump. By placing a charge pump in an isolated well 20 which is surrounded by regions of n-well 46 and p-well 48, it is possible to isolate the surrounding components from the electrical noise produced by the charge pump. To further bolster the isolation, p-well 48 is placed over a p+ buried layer 16. Due to its low resistivity, electrical noise within IC 2 and collected by p-well 48 can be effectively removed from IC 2. In this manner, the combination of p-well 48 and p+ buried layer 16 reduce the propagation of noise when integrating digital components 4, analog components 6, passive RF components 8, and active RF components 10 on single IC 2.

Active RF elements 10 such as heterojunction bipolar transistor 32 rest on high resistivity substrate 14. FIG. 1 includes the depiction of an NPN HBT device on a p-type substrate. Through placing HBT 32 on a highly resistive substrate 14, the capacitance between a collector well 60 and the substrate 14 depicted as Ccs, is minimized. Minimizing collector 60 substrate 14 capacitance maximizes the performance of HBT 32. In addition, active RF component 10 is surrounded by p-well 48 which serves to isolate HBT 32 from outside noise produced elsewhere on IC 2.

To further bolster the isolation provided by p-well 48 to HBT 32, p-well 48 rests upon a p+ buried layer 16. Due to its low resistivity, electrical noise within IC 2 is collected by p-well 48 from where it is removed from IC 2. In this manner, p-well 48 reduces the amount of noise that reaches HBT 32 that is produced elsewhere on IC 2. Electrical noise within IC 2 is also collected by p+ buried layer 16 due to its low resistivity from where it is removed from IC 2. In this manner, p+ buried layer 16 reduces the amount of noise that reaches HBT 32 from elsewhere on IC 2.

Passive RF circuit elements 8 such as inductor 70, for example, rest in or over a highly resistive region 16. The performance of passive RF components 8 is measured by the device quality factor. Passive components 8 having a low quality factor are undesirable in high frequency RF circuits. Low quality factor devices typically require the use of additional input stages to compensate for the loss of signal. Such additional input stages require additional chip space and increase device cost. To maximize the quality factor for inductor 70, and hence the performance of inductor 70, it is desirable to isolate inductor 70 from electrical noise produced from other devices on IC 2.

Inductor 70 is shown as a series of broken lines representing the coil that forms inductor 70. High resistivity substrate 14 attenuates noise signals generated elsewhere on IC 2 from reaching passive RF elements 8 such as inductor 70. In this manner, substrate 14 enhances the performance of inductor 70 and improves the quality factor through reducing inductor 70's exposure to noise. The improvement of the quality factor is most significant at high frequencies. Another passive RF element 8 is a capacitor, where although not shown, the same principles apply. In addition, through attenuating the signals generated elsewhere on IC 2, substrate 14 also reduces cross-talk.

In addition, the quality factor of inductor is further improved by its placement over high resistivity substrate 14. The high resistivity of substrate 14 retards the generation of electrical eddy currents beneath the inductor that degrade the performance of inductor 70.

A further manner of isolating passive RF elements 8 such as inductor 70 is by surrounding the high resistivity substrate 14 with a p-well isolation structure 72 and a p+ buried layer 74. The combination of p-well 72 and p+ buried layer 74 reduces the amount of electrical noise that inductor 70 is exposed to from the remainder of IC 2. Due to its low resistivity, this structure is able to collect and remove these signals from IC 2. In this manner, p-well 72 in combination with p+ buried layer 74 reduces the amount of noise that reaches inductor 70.

Isolating structure 12, comprised of patterned buried layer 16, high resistivity substrate 14, p-well 46 and 72, and n-well 48, reduces the problems of IC 2 noise and cross-talk that would inhibit the operation of analog 6 and RF components 8 and 10. Further, isolating structure 12 enhances the overall performance of digital components 4, analog components 6, passive RF components 8, and active RF components 10 through addressing the various parasitic problems encountered by each of these components.

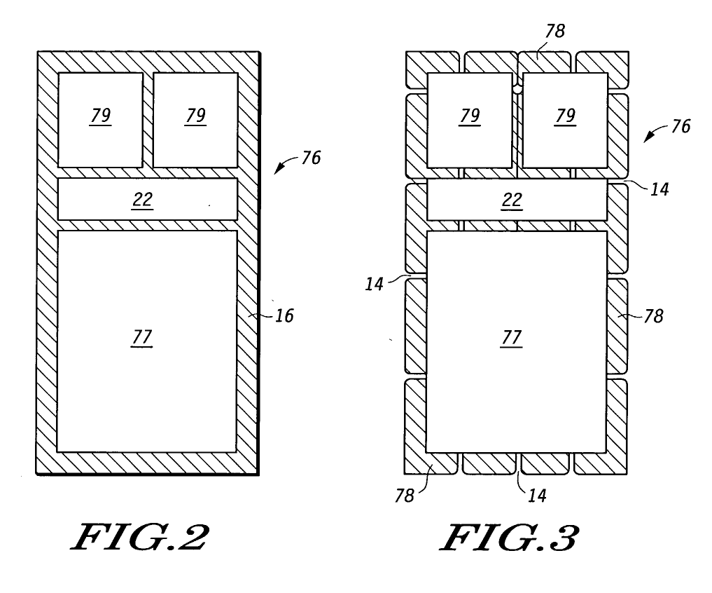

In a preferred embodiment, depicted in FIG. 2, a single buried layer 16 extends under all digital CMOS components 22 in a single digital circuit block 76. Through having a single buried layer 16 extend under the entire single digital circuit block 76, the occurrence of latch-up within these devices 22 is greatly reduced. Note that electrical noise produced from any area of block 76 is transmitted to every other area and device 22 within block 76 through buried layer 16. However, due to the nature of digital CMOS components 22, the performance of these devices 22 is not significantly degraded. Having a single buried layer 16 simplifies device architecture and reduces manufacturing processes and overall cost. Included in digital block 76 are CMOS 22, resistors 77, and other digital components 79.

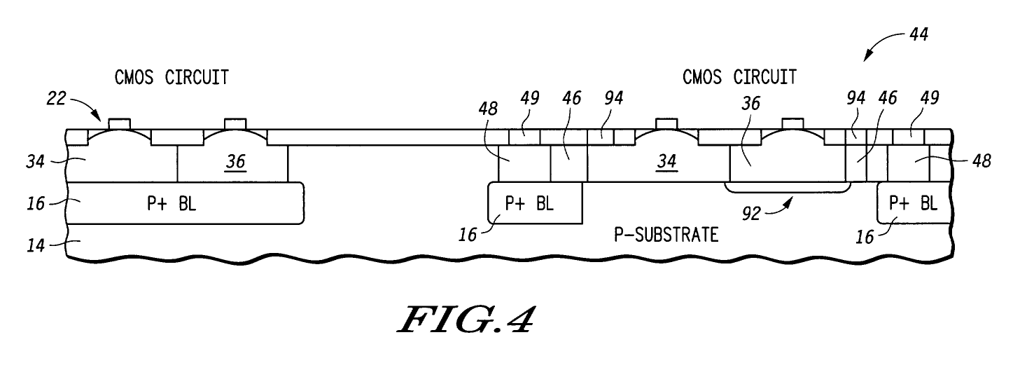

In an alternative embodiment, depicted in FIG. 3, buried layer 16 is broken into a series of blocks 78 extending under digital CMOS components 22 in a single digital circuit block 22. Between these blocks 78 is the highly resistive region 14. It can be desirable to break the buried layer 16 into a series of smaller blocks 78 in order to limit the transmission of electrical noise within the single digital circuit block 76. While electrical noise can travel relatively easily within the buried layer blocks 78, the highly resistive regions 14 between the buried layer blocks 78 impede and attenuate the transmission of noise from one buried layer block 78 to another buried layer block 78. Inter-block delineation with highly resistive regions 14 therefore limits noise transmission within single digital block 76.

FIG. 4 depicts a cross section of an isolated analog circuit element 6 in a preferred embodiment of the present invention. The example shown assumes use of a p-type substrate. Various regions shield the analog circuit from the noise produced by digital CMOS 22. First, the analog circuit 6 rests in a high resistivity region 14. The high resistivity of substrate 14 attenuates electrical signals produced from other devices. This high attenuation reduces the occurrence of device crosstalk. As depicted, on NMOS device 26 is comprised of a gate 80, a source 82, and a drain 84. A bulk contact 86 is provided for electrical communication with bulk region 88. The NMOS device 26 sits within an isolated p-well 90. Below isolated p-well 90 is an n-isolation region 92. N-isolation region 92 is connected to either or both the n-well ring 98 or n-well 46 to completely isolate the isolated p-well 90 from the p-type substrate 14 shown in this example. N-isolation region 92, together with n-well 46, collects electrical signals produced elsewhere on IC 2. These electrical signals are then removed from IC 2 with contact 94. In this manner, electrical signals produced elsewhere on IC 2 are removed from IC 2 thereby shielding analog circuit 6.

In a preferred embodiment, all n-wells 46 and n-well ring 98 are maintained at the same level of potential. N-wells 46 and n-well ring 98 are connected through n-isolation region 92. Contact 94 removes any electrical signal collected by n-wells 46, n-well ring 98, or n-isolation region 92 from IC 2. In this manner, n-wells 46, n-well ring 98, or n-isolation region 92 serve to insulate and isolate the various circuit components on IC 2 from electrical noise produced by digital CMOS 22 or other noisy electrical components like charge pumps.

FIG. 5 depicts a view of an isolated digital circuit block 76 fabricated in accordance with a preferred embodiment of the present invention. In a preferred embodiment, digital block 76 is comprised of digital CMOS circuitry 22 along with resistors 77 and other digital electrical components 79. Digital block 76 rests on single p+ buried layer 16. Through having single p+ buried layer 16 extend under the entire single digital circuit block 76, the likelihood of latch-up within these devices 22 is greatly reduced. Due to the large rail to rail voltage swings of digital CMOS 22, circuits 22 are electrically noisy. This electrical noise produced by digital CMOS 22 will propagate through substrate 14 to analog 6 and RF components 8 and 10 on IC 2 unless blocked or removed.

To isolate noisy digital CMOS circuits 22 from the remainder of IC 2, an n-well ring 98 is placed around digital block 76. This n-well ring 98 collects the electrical signals produced by digital CMOS 22. Contacts 94 connected to n-well ring 98 then remove electrical signals from IC 2. The n-well ring 98 is surrounded by an isolation p-well ring 100. A p+ source drain ring 102 is placed outside of isolation p-well ring 100. Together, these well rings 98, 100, 102 collect and remove electrical signals produced by digital CMOS 22.

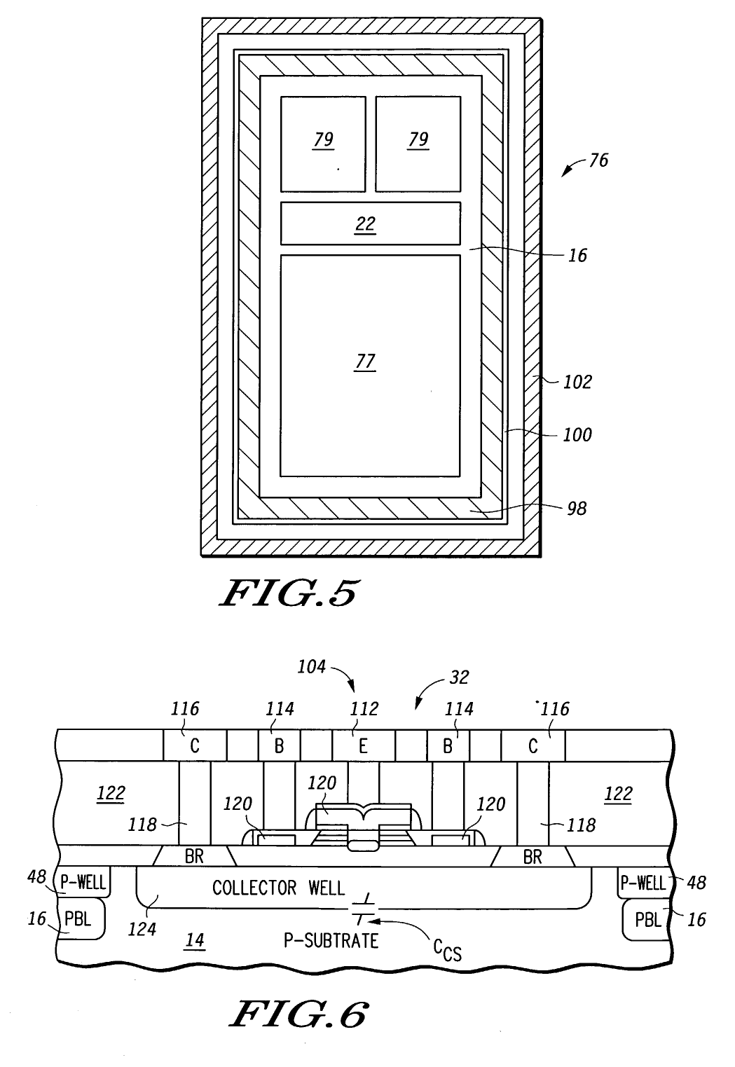

FIG. 6 depicts a heterojunction bipolar transistor (HBT) 32 formed in a integrated circuit 2 made in accordance with a preferred embodiment of the present invention. HBT 32 is comprised of quasi self-aligned structure 104 having an emitter 106, base 108, and a collector 110. Self-aligned structure 104 has reduced complexity and topography. It is desirable to use HBT 32 devices for active RF functions due to their ability to be integrated with CMOS components 22.

Emitter 112, base 114, and collector contact regions 116 are provided on a top surface of HBT 32. Vias 118 connect emitter 112, base 114, and collector contact regions. Insulating these vias is a dielectric material 122. A major source of HBT 32 performance degradation is the capacitance that forms between collector well 124 and the substrate 14. In order to maximize HBT 32 performance, it is necessary to minimize this collector 124 substrate 14 capacitance. Through placing HBT 32 directly on highly resistive substrate 14, this parasitic collector 124 substrate 14 capacitance is minimized.

HBT 32 is then isolated and insulated from electrical noise produced by other devices on IC 2 through the use of p-well 48 and p+ buried layer 16. P-well 48 and p+ buried layer 16 collect electrical signals produced elsewhere on the IC 2 and removes them from the system thereby isolating HBT 32. In this manner, electrical noise and cross-talk problems are reduced thereby enhancing the performance of HBT 32.

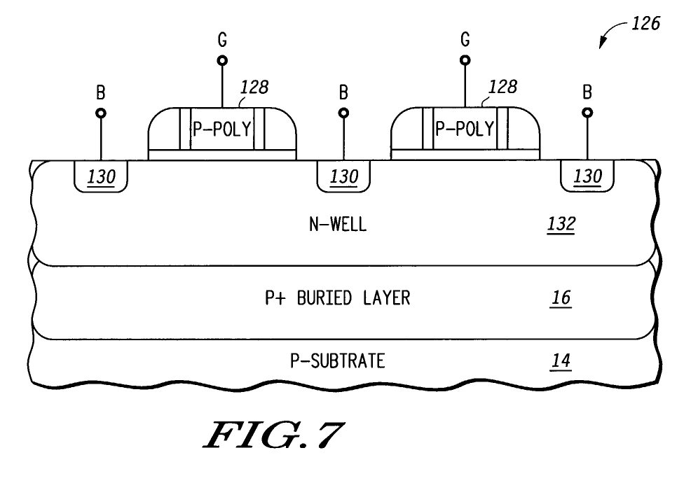

FIG. 7 depicts a varactor 126 formed in a integrated circuit 2 made in accordance with a preferred embodiment of the present invention. The term “varactor” comes from the words variable reactor and means a device whose reactance can be varied in a controlled manner with a bias voltage. Varactors 126 are widely used in parametric amplification, harmonic generation, mixing, detection, and voltage-variable tunning applications. Varactor 126, depicted in FIG. 7, over a p-type substrate and has gates 128 and base contacts 130 provided on n-well 132. Varactor 126 is placed over a p+ buried layer 16. As an active RF component 10, it is highly desirable to maximize the quality factor of varactor 126. Through placing varactor 126 in n-well 132, the quality factor is improved due to the low resistivity and isolation provided by n-well 132.

Those of skill will recognize that the present invention may be implemented with some or all of the methods and structures described herein and that, although, the present invention has been described in detail, it will be apparent to those of skill in the art that the invention may be embodied in a variety of specific forms and that various changes, substitutions, and alterations can be made without departing from the spirit and scope of the invention. The described embodiments are only illustrative and not restrictive and the scope of the invention is, therefore, indicated by the following claims.

We claim:

1) An integrated circuit, comprising:
a highly resistive substrate
a patterned low resistivity buried layer formed on said highly resistive substrate;
a digital circuit formed over said patterned low resistivity buried layer;
an analog circuit formed on said highly resistive substrate
a passive RF device formed on said highly resistive substrate; and
a well region surrounding said digital circuit.

2) The integrated circuit of claim 1, further comprising an active RF device.

3) The integrated circuit of claim 2, wherein said active RF device is formed on said highly resistive substrate.

4) The integrated circuit of claim 3, wherein said substrate is a p-substrate.

5) The integrated circuit of claim 3, wherein said substrate is a n-substrate.

6) The integrated circuit of claim 4, wherein said patterned low resistivity buried layer is a p+ buried layer.

7) The integrated circuit of claim 5, wherein said patterned low resistivity buried layer is an n+ buried layer.

8) The integrated circuit of claim 6, wherein said passive RF device is surrounded by a p-well.

9) The integrated circuit of claim 8, wherein said passive RF device is surrounded by a n-well.

10) An integrated circuit comprising:
a digital circuit;
an analog circuit;
a passive RF device;
an active RF device;
a p+ buried layer, said digital circuit formed on said p+ buried layer;
a p− epilayer, said analog circuit formed on said p− epilayer, said passive RF device formed on said p− epilayer;
a substrate, said substrate supports said p+ buried layer and said p− epilayer, said active RF device formed on said substrate.

11) The integrated circuit of claim 10, further comprising a well region surrounding said digital circuit.

12) The integrated circuit of claim 11, further comprising a well region surrounding said analog circuit.

13) The integrated circuit of claim 12, further comprising a well region surrounding said passive RF device.

14) The integrated circuit of claim 13, further comprising a well region surrounding said active RF device.

15) The integrated circuit of claim 14, further comprising:
a p+ buried layer formed under said well region surrounding said passive RF device; and
a p+ buried layer formed under said well region surrounding said active RF device.

16) An integrated circuit, comprising:
a digital circuit;
an analog circuit;
an active RF device;
a passive RF device;
high resistivity means formed under said analog circuit to attenuate the transmission of electrical signals between said electrical circuit and said analog circuit;
low resistivity means formed under said digital circuit to prevent latch-up from occurring in said digital circuit;
high resistivity means to have a low capacitance between a substrate and a collector in said active RF device;
high resistivity means under said passive RF component to improve the quality factor of said RF component; and
well means surrounding said digital circuit to collect electrical signals produced by said digital circuit.

17) The integrated circuit of claim 16, further comprising buried layer means formed under said well means to collect electrical signals produced by said digital circuit.

18) A method of increasing the performance of an integrated circuit, comprising the steps of:
attenuating an electrical signal produced by a digital circuit with a high resistivity epilayer;
collecting an electrical signal produced by said digital circuit with a low resistivity buried layer;
collecting said electrical signal produced by a digital circuit with a low resistivity well region that surround said digital circuit;
reducing latch-up in said digital circuit with said low resistivity buried layer;
decreasing a capacitance between a collector region and a substrate in a heterojunction bipolar transistor;

19) The method of claim 18, further comprising the step of collecting said electrical signal with a low resistivity well region surrounding a passive RF device.

20) The method of claim 19, further comprising the step of collecting said electrical signal with a low resistivity well region surrounding an active RF device.

21) The method of claim 20, further comprising the step of collecting said electrical signal with a low resistivity buried layer formed under said low resistivity well region surrounding said passive RF device.

22) The method of claim 21, further comprising the step of collecting said electrical signal with a low resistivity buried layer formed under said low resistivity well region surrounding said active RF device.
